(19) United States
(12) Patent Application Publication
(10) Pub. No.: US 2021/0091253 A1
(43) Pub. Date: Mar. 25, 2021

(54) DISPLAY DEVICE AND MANUFACTURING METHOD THEREOF

(71) Applicant: INT TECH CO., LTD., HSINCHU COUNTY (TW)

(72) Inventors: FU-YUAN TUAN, NEW TAIPEI CITY (TW); LONG-MING LU, TAIPEI CITY (TW); SHIN-SHIAN LEE, HSINCHU CITY (TW); KUO-CHENG HSU, TAICHUNG CITY (TW); HUEI-SIOU CHEN, TAIPEI CITY (TW)

(21) Appl. No.: 17/009,419

(22) Filed: Sep. 1, 2020

Related U.S. Application Data
(60) Provisional application No. 62/903,330, filed on Sep. 20, 2019.

(30) Foreign Application Priority Data
Aug. 10, 2020 (CN) 202010796613.6

(51) Int. Cl. H01L 31/12; H01L 31/101; H01L 31/18; H01L 27/32

(52) U.S. Cl. CPC H01L 31/125; H01L 27/3227; H01L 31/186; H01L 31/101

(57) ABSTRACT

A display device includes a substrate and an optical sensing unit disposed on the substrate. The optical sensing unit includes a photodiode, a dielectric layer, and a second electrode. The photodiode is disposed on the substrate and includes a sidewall and an upper surface. The dielectric layer is disposed on the substrate and on the sidewall of the photodiode, and is in contact with a first portion of the upper surface of the photodiode. The second electrode includes a first conductive layer and a second conductive layer, wherein the first conductive layer is disposed on a second portion of the upper surface of the photodiode, and the second conductive layer is disposed between the dielectric layer and the first conductive layer. The first portion of the upper surface of the photodiode encircles the second portion.

### PRIORITY CLAIM AND CROSS REFERENCE

This application claims the priority to U.S. Provisional Patent application No. 62/903,330 filed on Sep. 20, 2019 and China Patent Application Serial No. 202010796613.6 filed on Aug. 10, 2020. The entire disclosures of the patent applications are incorporated herein by reference.

### BACKGROUND OF THE INVENTION

### Field of the Invention

The present invention relates to a display device and a manufacturing method thereof, and more particularly, to a display device including a photodiode and a manufacturing method thereof.

### Description of the Prior Art

Display devices including optical sensors are extensively applied in most electronic devices, while there are demands for large display devices in the recent years. However, as display technologies continue to progress, the number of pixels within each unit size is also increased, such that the dimensions of devices for displaying each pixel need to be correspondingly reduced. In fact, one commonly acknowledged challenge in the present field is to simultaneously improve light extraction efficiency while reducing device dimensions. Therefore, there is a need for a solution for resolving the above issues in the industry of display devices.

### SUMMARY OF THE INVENTION

A display device includes a substrate, and a sensing unit disposed on the substrate. The sensing unit includes a photodiode, a dielectric layer and a second electrode. The photodiode is disposed on the substrate, and includes a sidewall and an upper surface. The dielectric layer is disposed on the substrate and on the sidewall of the photodiode, and is in contact with a first portion of the upper surface of the photodiode. The second electrode includes a first conductive layer and a second conductive layer. The first conductive layer is disposed on a second portion of the upper surface of the photodiode, and the second conductive layer is disposed on the dielectric layer and on the first conductive layer. The first portion of the upper surface of the photodiode encircles the second portion.

A display device includes a substrate, a photodiode, a first conductive layer, a second conductive layer, and a dielectric layer. The photodiode is disposed on the substrate and included an upper surface. The first conductive layer is disposed on the photodiode. The second conductive layer is disposed between the photodiode and the first conductive layer, and electrically connected to the photodiode and the first conductive layer. The dielectric layer is disposed between the photodiode and the first conductive layer, and adjacent to the second conductive layer. The upper surface of the photodiode has a first joint joined with the second conductive layer and the dielectric layer.

A method for manufacturing a display device includes forming a first electrode layer on a substrate; forming an optical sensing layer on the first electrode; forming a first conductive layer on the optical sensing layer; and forming a photosensitive layer on the first conductive layer. The method further includes patterning the first conductive layer and the optical sensing layer to form a photodiode and a first opening exposing the first electrode, wherein an upper surface of the photodiode comprises a first portion that is exposed and a second portion covered by the first conductive layer; forming a dielectric layer in the first opening, and on the first conductive layer, the sidewall of the photodiode and the first portion of the upper surface of the photodiode; patterning the dielectric layer to form a second opening exposing the first conductive layer; and forming a second conductive layer in the second opening and on the dielectric layer.

### BRIEF DESCRIPTION OF THE DRAWINGS

FIG. 1 is a top view of an intermediate product of a display device according to some embodiments;

FIG. 2 is a section diagram of a display device according to some embodiments;

FIG. 3 is a partial top view of a display device according to some embodiments;

FIG. 4 is a section diagram of a display device according to some embodiments;

FIG. 5 is a partial top view of a display device according to some embodiments;

FIG. 6 is a section diagram of a display device according to some embodiments;

FIG. 7 is a section diagram of a display device according to some embodiments;

FIG. 8 is a section diagram of a display device according to some embodiments;

FIG. 9 is a top view of a display device according to some embodiments;

FIG. 10 is a top view of a display device according to some embodiments;

FIG. 11 is a top view of a display device according to some embodiments;

FIG. 12 is a section diagram of a display device according to some embodiments;

FIG. 13 is a top view of a display device according to some embodiments;

FIG. 14 is a flowchart of a method for forming a display device according to some embodiments; and

FIG. 15 to FIG. 23 are brief diagrams for illustrating optical sensors in different manufacturing stages of a method according to some embodiments of the present disclosure.

### DETAILED DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the term “about” generally means within 10%, 5%, 1%, or 0.5% of a given value or range. Alternatively, the term “about” means within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the term “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

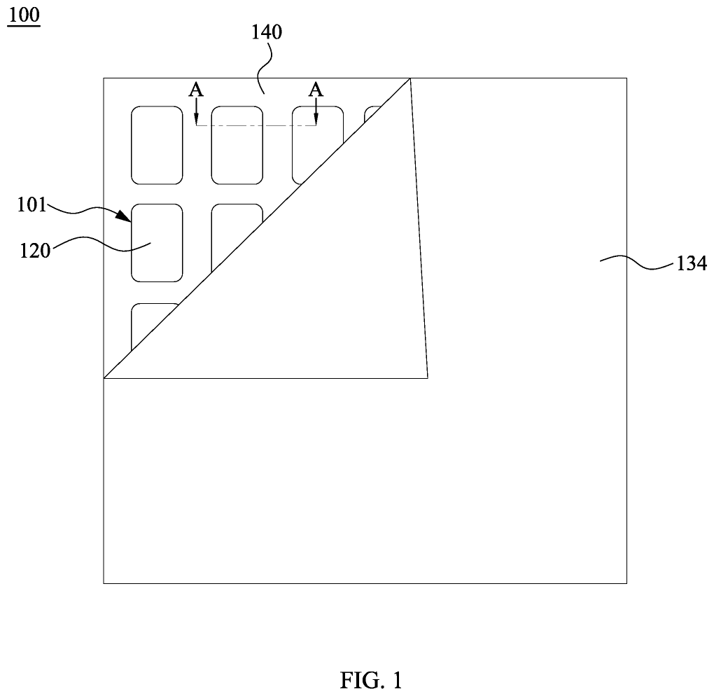

FIG. 1 shows a top view of a display device 100 according to some embodiments of the present disclosure, and depicts an example of an intermediate product of the display device 100. The display device 100 includes a plurality of sensing units 101, and a second conductive layer 134 located on the sensing units 101. In some embodiments, the sensing units 101 are arranged in an array. In some embodiments, the sensing units 101 include photodiodes 120 exposed from the dielectric layer 140. In some embodiments, the display device 100 may include a protrusion array of a plurality of photodiodes 120, and the plurality of photodiodes 120 are separated from one another by the dielectric layer 140.

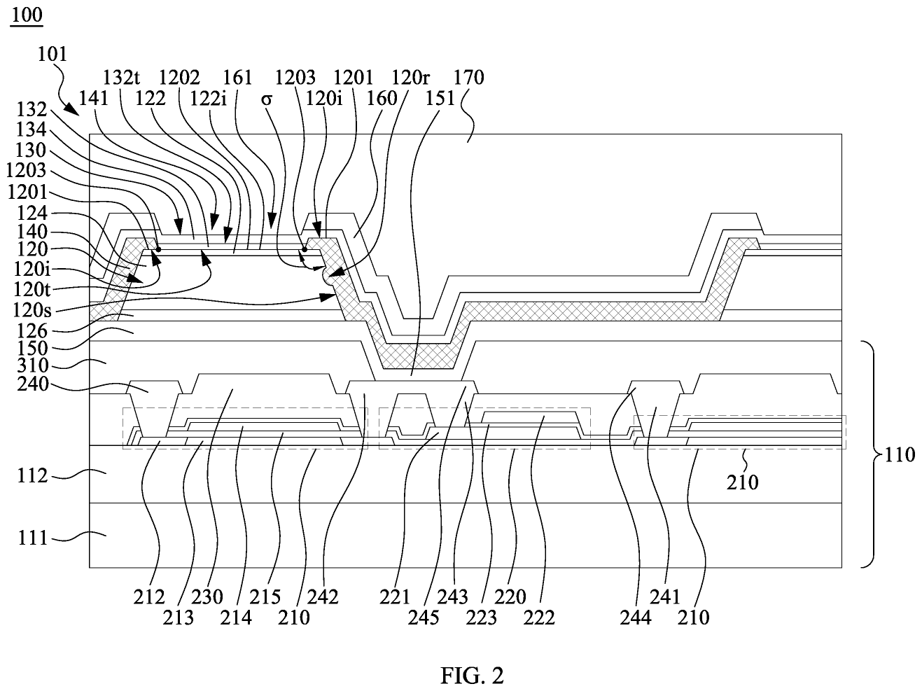

FIG. 2 shows a section diagram of the display device 100 along the line AA in FIG. 1 according to some embodiments of the present disclosure. The display device 100 includes a substrate 110 and a sensing unit 101. The sensing unit 101 is disposed on the substrate 110, and includes a photodiode 120 disposed on the substrate 110. The photodiode 120 includes a sidewall 120s and an upper surface 120t. A dielectric layer 140 is disposed on the substrate 110 and on the sidewall 120s of the photodiode 120, and is in contact with a first portion 1201 of the upper surface 120t of the photodiode 120. The sensing unit 101 further includes a second electrode 130, which includes a first conductive layer 132 and a second conductive layer 134. The first conductive layer 132 is disposed on a second portion 1202 of the upper surface 120t of the photodiode 120, and the second conductive layer 134 is disposed on the dielectric layer 140 and on the first conductive layer 132. The first portion 1201 of the upper surface 120t of the photodiode 120 encircles the second portion 1202.

The substrate 110 includes a base material 111, a dielectric layer 112, and one or more circuits disposed on the base material 111. In some embodiments, the base material 111 is a transparent base material, or at least a portion of the base material is transparent. In some embodiments, the base material 111 is a non-flexible base material, and may include such as glass, quartz, low-temperature polysilicon (LTPS) or other appropriate materials. In some embodiments, the base material 111 is a flexible base material, and may include such as transparent epoxy resin, polyimide, polyvinyl chloride, methyl methacrylate or other appropriate materials. The dielectric layer 112 may be disposed on the base material 111 according to requirements, as shown in FIG. 1. In some embodiments, the dielectric layer 112 may include such as silicon oxide, silicon nitride, silicon oxynitride or other appropriate materials.

In some embodiments, the circuits may include CMOS circuits, or may include a plurality of transistors 210 and a plurality of capacitors 220 near the transistors, wherein the transistors 210 and the capacitors 220 are formed on the dielectric layer 112. In some embodiments, each transistor 220 is a thin-film transistor (TFT). Each transistor 220 includes a source/drain region 212 (including at least one source region and one drain region), a channel region 213 between the source/drain region 212, a gate electrode 214 disposed on the channel region 213, and a gate insulator 215 between the channel region 213 and the gate electrode 214. The gate electrode 214 may be made of an electrically conductive material, for example, a metal, silicide or metal alloy. In some embodiments, the gate electrode 214 may be a compositive structure including a plurality of different layers, and these layers may be applied with an etching agent and hence be differentiated from one another when observed under a microscope. In some embodiments, the gate electrode 214 and a first metal layer of an interlayer dielectric structure 230 are simultaneously formed. The interlayer dielectric structure 230 is disposed on the circuits or the transistors 210. The interlayer dielectric structure 230 may include a plurality of layers of metal wires and dielectric materials, so as to provide electrical connection or insulation. The channel region 213 of the transistor 210 may be made of a semiconductor material, for example, silicon or other elements selected from group IV, group III or group V.

In some embodiments, the gate insulator 215 covers the channel region 213 and the source/drain region 212 of the transistor 210, and the gate insulator 215 is disposed between the capacitor 220 and the dielectric layer 112 adjacent to each other. In some embodiments, after the source/drain region 212 and the channel region 213 are formed on the dielectric layer 112, the gate insulator 215 is formed. The source/drain regions 212 are disposed on opposite sides of the channel region 213 so as to provide carriers. In some embodiments, the capacitor 220 is disposed between two transistors 210. Each capacitor 220 includes a lower electrode 221, an upper electrode 222 and an insulation layer 223 between the upper electrode 222 and the lower electrode 221. In some embodiments, the lower electrode 221 and the first metal layer of the interlayer dielectric structure 230 on the dielectric layer 112 are simultaneously formed. In some embodiments, the insulation layer 223 is formed on the transistor 210 only after the first metal layer is formed. In some embodiments, the insulation layer 223 is disposed on and is conformal with the lower electrode 221 and the transistor 210. The upper electrode 222 is disposed on the insulation layer 223 in the interlayer dielectric structure 230. The upper electrode 222 may include titanium, aluminium, copper, titanium nitride or a combination thereof, or other appropriate materials. In some embodiments, the upper electrode 222 and a second metal layer of the interlayer dielectric structure 230 are simultaneously formed. In some embodiments, the upper electrode 222 and the second metal layer are formed after the insulation layer 223 is formed.

In some embodiments, a connecting structure 240 electrically connects the transistor 210 to the capacitor 220. The connecting structure 240 includes a plurality of connecting paths and a plurality of connecting wires. The connecting paths may be connected to the source/drain region 212 of the transistor 210, the gate electrode 214 of the transistor 210, and the lower electrode 221 and/or the upper electrode 222 of the capacitor 220 and may be connected to the connecting wires, so as to form an integrated circuit on the base material 111. The connecting structure 240 may include some connecting paths 241, with one ends thereof connected to the drain region 212 of the transistor 210. The connecting structure 240 may include some connecting paths 242, with one ends thereof connected to the source region 212 of the transistor 210. The connecting structure 240 may include some connecting paths 243, with one ends thereof connected to the lower electrode 221 of the capacitor 220. The connecting structure 240 may include some connecting wires 244, with one end thereof respectively connected to the connecting paths 241. The connecting structure 240 may include some connecting wires, with one ends thereof only respectively connected to the connecting paths 242 (not shown). The connecting structure 240 may further include some connecting wires 245, with one ends thereof connected to the connecting paths 242 and the connecting paths 243. In some embodiments, the foregoing connecting wires are formed simultaneously when a metal layer (for example, a third metal layer) of the interlayer dielectric structure 230 is formed.

A data line (not shown) is disposed on the connecting wires of the connecting structure 240 so as to be electrically connected to the source/drain region 212. A dielectric layer 310 is disposed on the data line, the interlayer dielectric structure 230 and the connecting structure 240. In some embodiments, the dielectric layer 310 is formed by means of conformal deposition. The dielectric layer 310 and the structures below may be conformal in shape. A planar layer 320 is disposed on the dielectric layer 310. In some embodiments, the planar layer 320 includes a dielectric or insulative material. In some embodiments, the planar layer 320 is formed by means of coating deposition, wherein the lower surface of one planar layer 320 and the structure below are conformal in shape, and the upper surface of the planar layer 320 is substantially planar. In some embodiments, the dielectric layer 310 includes a through via (or an opening) located on the connecting wire 245, and the connecting wire 245 is exposed from the dielectric layer 310 through the foregoing through via.

In the display device 100, the first electrode 150 is disposed on the dielectric layer 310, wherein a portion of the first electrode 150 passes through the dielectric layer 310 so as to be electrically connected to the connecting wire 245. In some embodiments, the first electrode 150 has a flat surface as the substrate 110, and is electrically connected to the transistor 210 and/or the capacitor 220 by a conductive plug (not shown) and the connecting structure 240 (including the connecting paths 242 and 243 and the connecting wire 245), wherein the conductive plug is encircled by the dielectric layer 310. In some embodiments, the first electrode 150 includes a recessed portion 151, and the first electrode 150 is electrically connected to the transistor 210 and/or the capacitor 220 through the recessed portion 151 and the connecting structure 240 (including the connecting paths 242 and 243 and the connecting wire 245). From a section view, the recessed portion 151 of the first electrode 150 is encircled by the dielectric layer 310. In some embodiments, the recessed portion 151 of the first electrode 150 is electrically connected to the transistor 210 through a conductive material or an electronic element. In some embodiments, the bottom of the recessed portion 151 of the first electrode 150 is in physical contact with the connecting wire 245. In some embodiment, the bottom of the recessed portion 151 of the first electrode 150 overlaps with the connecting wire 245. In some embodiments, the recessed portion 151 may be, for example, a U-shaped portion or a V-shaped portion.

The display device 100 includes a sensing unit 101. The sensing unit 101 includes a photodiode 120 disposed on the substrate 110. In some embodiments, the photodiode 120 is disposed on the first electrode 150.

In some embodiments, the photodiode 120 is disposed on the first electrode 150 and is in an alternating arrangement with respect to the recessed portion 151 of the first electrode 150. In some embodiments, the photodiode 120 is a PIN optical sensor, which includes an N-type doped layer 126, an intrinsic layer 124 and a P-type doped layer 122 sequentially stacked on the first electrode 150. In some embodiments, the photodiode 120 is a PN optical sensor, which includes an N-type doped layer 126 and a P-type doped layer 122 sequentially stacked on the first electrode 150. In some embodiments, the photodiode 120 is an IPIN optical sensor, which includes an N-type doped layer 126, a first intrinsic layer 124, a P-type doped layer 122 and a second intrinsic layer (not shown) sequentially stacked on the first electrode 150. In some embodiments, the photodiode 120 is an IN optical sensor, which includes an N-type doped layer 126 and an intrinsic layer 124 sequentially stacked on the first electrode 150. In some embodiments, each of the N-type doped layer 126, the intrinsic layer 124 and the P-type doped layer 122 are selected form a group consisting of a a-silicon layer, a crystallization-silicon layer, a poly-silicon layer, and Side layer. In some embodiments, the thickness of the N-type doped layer 126 is within a range of 1 to 200 nm. In some embodiments, the thickness of the intrinsic layer 124 is within a range of 100 to 1000 nm. In some embodiments, the thickness of the P-type doped layer 122 is within a range of 1 to 200 nm.

In some embodiments, the photodiode 120 includes a sidewall 120s and an upper surface 120t. In some embodiments, the upper surface 120t is an upper surface of the P-type doped layer 122. In some embodiments, a contact area of the photodiode 120 with the first electrode 150 is greater than a contact area of the photodiode 120 with the first conductive layer 132. In some embodiments, the photodiode 120 is rectangular or quadrilateral in shape. In some embodiments, the photodiode 120 is trapezoidal or inverted trapezoidal in shape. In some embodiments, the sidewall 120s and the upper surface 120t have therebetween a radius angle σ, which is within a range of 75 degrees to 160 degrees. In some embodiments, the radius angle σ is within a range of 90 degrees to 120 degrees. In some embodiments, the radius angle σ is within a range of 90 degrees to 105 degrees. In some embodiments, the sidewall 120s has a recess 120r. In some embodiments, the recess 120r is formed on the intrinsic layer 124 or the P-type doped layer 122.

The dielectric layer 140 is disposed between the photodiode 120 and the second conductive layer 134, and is adjacent to the first conductive layer 132. The dielectric layer 140 is further disposed between the adjacent sensing units 101 on the substrate 110 and on the sidewall 120s of the photodiode 120, and extends to become in contact with the first portion 1201 of the upper surface 120t of the photodiode 120. In some embodiments, the dielectric layer 140 encircles the sidewall 120s of the photodiode 120. In some embodiments, the dielectric layer 140 is further disposed in the recess 120r. In some embodiments, the thickness of the dielectric layer 140 is within a range of 100 to 800 nm. In some embodiments, the dielectric layer 140 includes silicon oxide, silicon nitride, silicon oxynitride or other appropriate materials. In some embodiments, the dielectric layer 140 continuously covers a plurality of sensing units 101.

In some embodiments, it is observed from a section angle, the upper surface 120t of the photodiode 120 has a joint 1203 that joins with the second conductive layer 132 and the dielectric layer 140. In some embodiments, the upper surface 120t has two joints 1203 respectively located on two ends of the dielectric layer 140. In some embodiments, the upper surface 120t of the photodiode 120 and the dielectric layer 140 are in contact between the joint 1203 and the sidewall 120s; that is, the first portion 1201 is in contact with the dielectric layer 140 but is not in contact with the first electrode 132, so as to reduce the possibility of current leakage at the sidewall 120s of the photodiode 120. The upper surface is in contact with the first electrode 132 between the two joints 1203. In some embodiments, the joint 1203 distinguishes the first portion 1201 and the second portion 1202 of the upper surface 120t. In some embodiments, the thickness uniformity of the first portion 1201 is greater than the thickness uniformity of the second portion 1202.

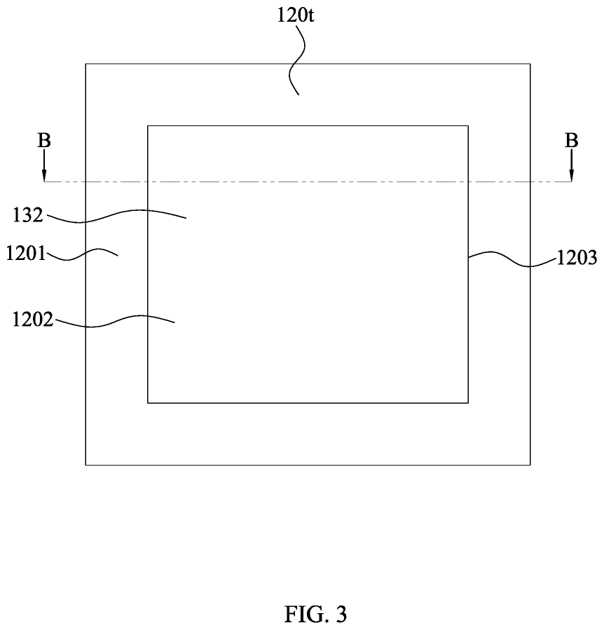

FIG. 3 shows a top view of the sensing unit 101 in FIG. 2 (the section of FIG. 2 is obtained along the line B-B in FIG. 3). As shown in FIG. 3, the first portion 1201 and the second portion 1202 are rectangular in shape; however, the shapes thereof may be different, depending on designer preferences. The surface area of each portion is determined by the position of the joint 1203. The surface area of the first portion 1201 and the surface area of the second portion 1202 may be equal or different. In some embodiments, the surface area of the first portion 1201 is smaller than the surface area of the second portion 102.

Again referring to FIG. 2, in some embodiments, the dielectric layer 140 has an opening 141 for light to pass through and to enter the photodiode 120. In some embodiments, the exposed portion of the opening 141 is the second portion 1202 of the upper surface 120t. In some embodiments, the first conductive layer 132 is disposed in the opening 141, and is in physical contact with the second portion 1202 of the upper surface 102t. In some embodiments, the dielectric layer 140 encircles the first conductive layer 132.

In some embodiments, a first interface 120i is included between one end of the upper surface of the photodiode and one end of the first conductive layer 132, and is between the dielectric layer 140 and the photodiode 120. In some embodiments, a second interface 122i is included between one end and the other end of the first conductive layer 132, and is between the first conductive layer 132 and the photodiode 120. In some embodiments, the thickness uniformity of the first interface 120i is greater than the thickness uniformity of the second interface 122i.

In some embodiments, the first interface 120i is located on the first portion 1201 of the upper surface 120t of the photodiode 120. In some embodiments, the second interface 122i is located on the second portion 1202 of the upper surface 120t of the photodiode 120. In some embodiments, the first interface 120i and the second interface 122i are distinguished by the joint 1203.

In some embodiments, the first conductive layer 132 is transparent. In some embodiments, the first conductive layer 132 includes an electrode material, for example but not limited to, indium tin oxide (ITO), molybdenum or a combination thereof. In some embodiments, the thickness of the first conductive layer 132 is within a range of 5 to 50 nm. In some embodiments, the thickness of the first conductive layer 132 is smaller than the thickness of the dielectric layer 140. In some embodiments, the thickness uniformity of the first conductive layer 132 is greater than the thickness uniformity of the second portion 1202 of the upper surface 120t of the photodiode 120.

In some embodiments, the second conductive layer 134 is continuously disposed on the first conductive layer 132 and the dielectric layer 140. The first conductive layer 132 and the second conductive layer 134 form the second electrode 130, such that the second electrode 130 is multilayered. In some embodiments, the second conductive layer 134 is continuously lined among a plurality of sensing units 101. In some embodiments, the second conductive layer 134 and the first conductive layer 132 are conformal with the dielectric layer 140. In some embodiments, the entire upper surface of the first conductive layer 132 is in contact with the second conductive layer 134.

In some embodiments, the thickness of the second conductive layer 134 is within a range of 5 to 200 nm. In some embodiments, the thickness of the first conductive layer 132 is smaller than or equal to the thickness of the second conductive layer 134. In some embodiments, the second conductive layer 134 is transparent. The second conductive layer 134 includes an electrode material, for example to not limited to, ITO. In some embodiments, the second conductive layer 134 includes an electrode material same with that of the first conductive layer 132.

In some embodiments, the second conductive layer 134 is treated so that the roughness of the upper surface is increased and the photon absorption rate of the sensing unit 101 is also increased, thereby enhancing quantum efficiency and light extraction rate. In some embodiments, the thickness uniformity of the second conductive layer 134 is greater than the thickness uniformity of the upper surface 120t of the photodiode 120. In some embodiments, the thickness uniformity of the second conductive layer 134 is greater than that of the first conductive layer 132.

In some embodiments, the display device 100 further includes a first shielding metal layer 160 disposed on the second electrode 130. In some embodiments, the first shielding metal layer 160 is disposed on the second conductive layer 134. In some embodiments, the first shielding metal layer 160 and the second conductive layer 134 are conformal. In some embodiments, the first shielding metal layer 160 includes aluminum, ITO or a combination thereof. In some embodiments, the first shielding metal layer 160 includes a multilayered structure, for example but not limited to, a combination of an aluminum layer (not shown) and an ITO layer (not shown). The thickness of the aluminum layer may be, for example but not limited to, 100 to 500 nm. The thickness of the ITO layer may be, for example but not limited to, 5 to 50 nm. In some embodiments, the aluminum layer is disposed on the second electrode 130, and the ITO layer is disposed on the aluminum layer.

In some embodiments, the first shielding metal layer 160 includes a first opening 161, which is for light to pass through and to enter the photodiode 120. The first opening 161 exposes a portion of the second electrode 134. In some embodiments, the first opening 161 overlaps with the opening 141 of the dielectric layer 140.

In some embodiments, the display device 100 further includes a flat layer 170 disposed on the first shielding metal layer 160. In some embodiments, the flat layer 170 is capable of withstanding a temperature of 280° C. or more. In some embodiments, the transmittance of the flat layer 170 is 99% or more.

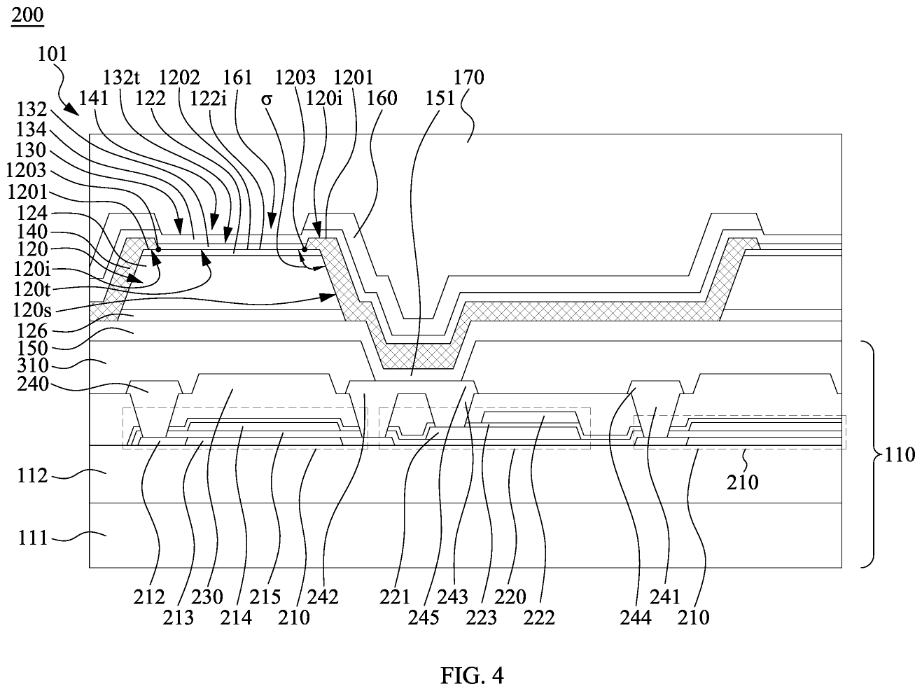

FIG. 4 shows a section diagram of a display device 200 according to some embodiments of the present disclosure. In some embodiments, as shown in FIG. 4, the dielectric layer 140 is in contact with part of the upper surface 132t of the first conductive layer 132. In some embodiments, the upper surface 132t of the first conductive layer 132 has a first portion 1321 in contact with the dielectric layer 140 and a second portion 1322 in contact with the second conductive layer 134.

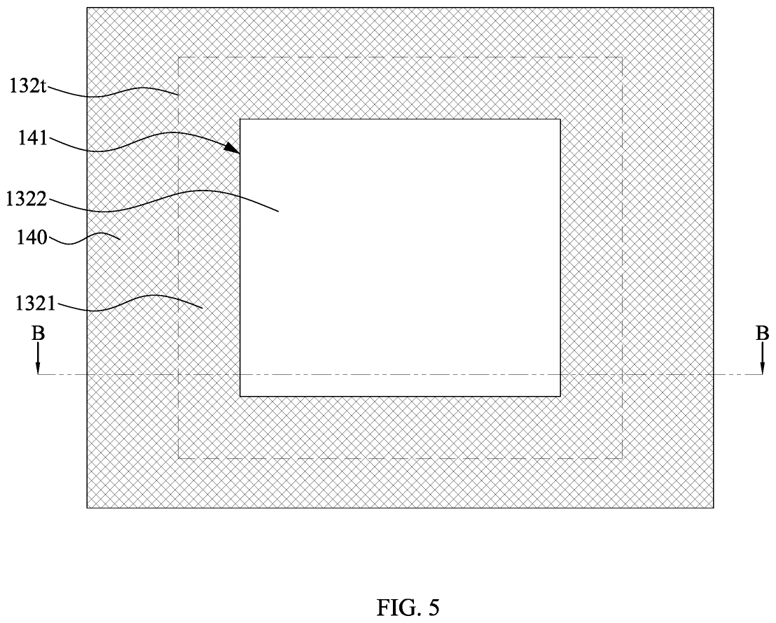

FIG. 5 shows a top view of the sensing unit 101 in FIG. 4 (the section of FIG. 4 is obtained along the line C-C in FIG. 5). In some embodiments, as shown in FIG. 5, the first portion 1321 of the upper surface 132 of the first conductive layer 132 encircles the second portion 1322. In some embodiments, the first portion 1321 and the second portion 1322 of the upper surface 132t of the first conductive layer 132 are rectangular in shape; however, different shapes may be used, depending on designer preferences. The position and surface area of each of the portions 1321 and 1322 are determined by the position of the opening 141 of the dielectric layer 140. The surface area of the first portion 1321 and the surface area of the second portion 1322 may be equal or different. In some embodiments, the surface area of the first portion 1321 is smaller than the surface are of the second portion 1322.

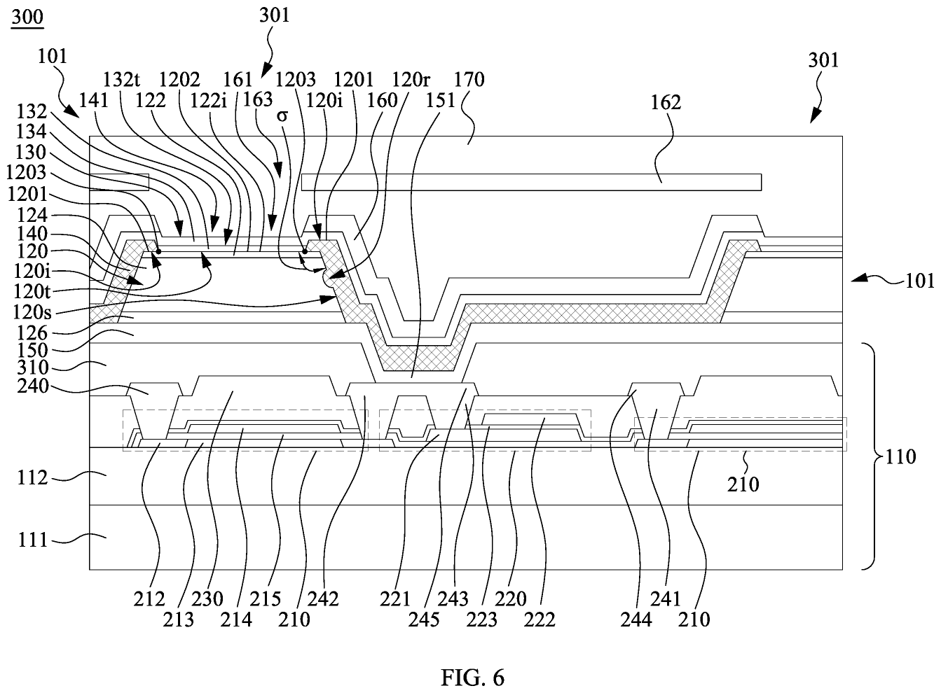

FIG. 6 shows a section diagram of a display device 300 according to some embodiments of the present disclosure. In some embodiments, as shown in FIG. 6, the display device 300 includes a regular pixel 301, into which light may enter. In some embodiments, the regular pixel 301 includes a second shielding metal layer 162, which is located on the sensing unit 101 and the first shielding metal layer 160 and is disposed in a flat layer 170. In some embodiments, the second shielding metal layer 162 further includes an opening 163. The opening 163 of the second shielding metal layer 162 and the first opening 161 of the first shielding metal layer 160 allow light to enter the sensing unit 101. In some embodiments, the opening 163 of the second shielding metal layer 162 partially overlaps with the first opening 161 of the first shielding metal layer 160. The width of the opening 163 of the second shielding metal layer 162 and the width of the first opening 161 of the first shielding metal layer 160 may be equal or different. In some embodiments, the second shielding metal layer 162 includes a multilayered structure, for example but not limited to, a combination of an aluminum layer (not shown) and an ITO layer (not shown).

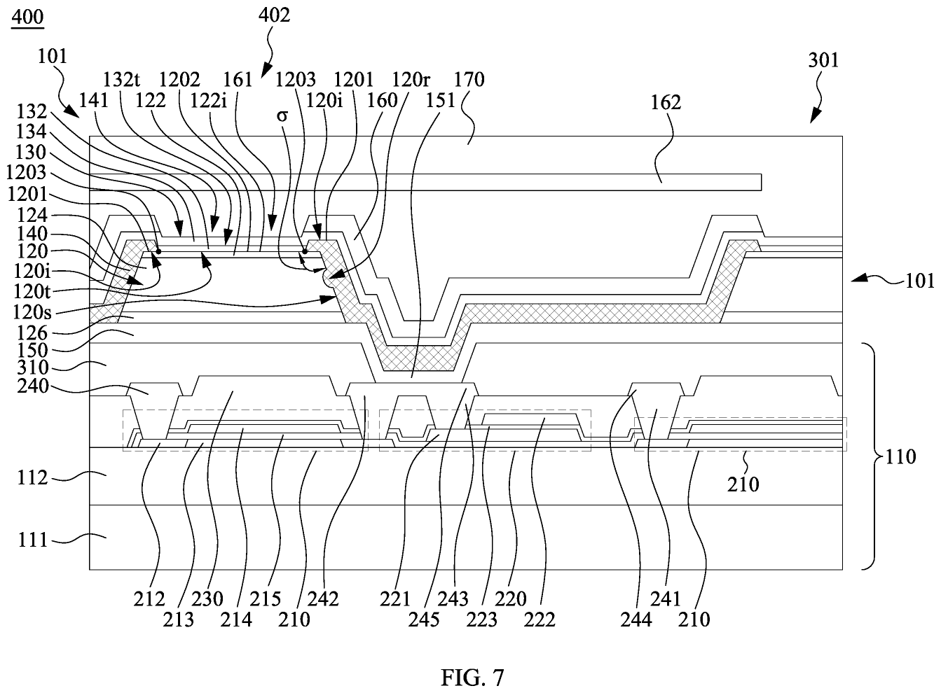

FIG. 7 shows a section diagram of a display device 400 according to some embodiments of the present disclosure. In some embodiments, as shown in FIG. 7, the display device 400 includes a regular pixel 301 and a dark pixel 402, wherein light cannot enter the dark pixel 402. In some embodiments, the quantum efficiencies of the regular pixel 301 and the dark pixel 402 are compared so as to learn background noise of the display device 400.

In some embodiments, the dark pixel 402 includes a second shielding metal layer 162, which is located on the sensing unit 101 and the first shielding metal layer 160 and is disposed in a flat layer 170. In some embodiments, the second shielding metal layer 162 is formed on the first opening 161 of the first shielding metal layer 160, prohibiting light from entering the sensing unit 101 of the dark pixel 402. In some embodiments, the second shielding metal layer 162 partially overlaps with the first opening 161 of the first shielding metal layer 160. The width of the second shielding metal layer 162 is greater than the width of the first opening 161 of the first shielding metal layer 160.

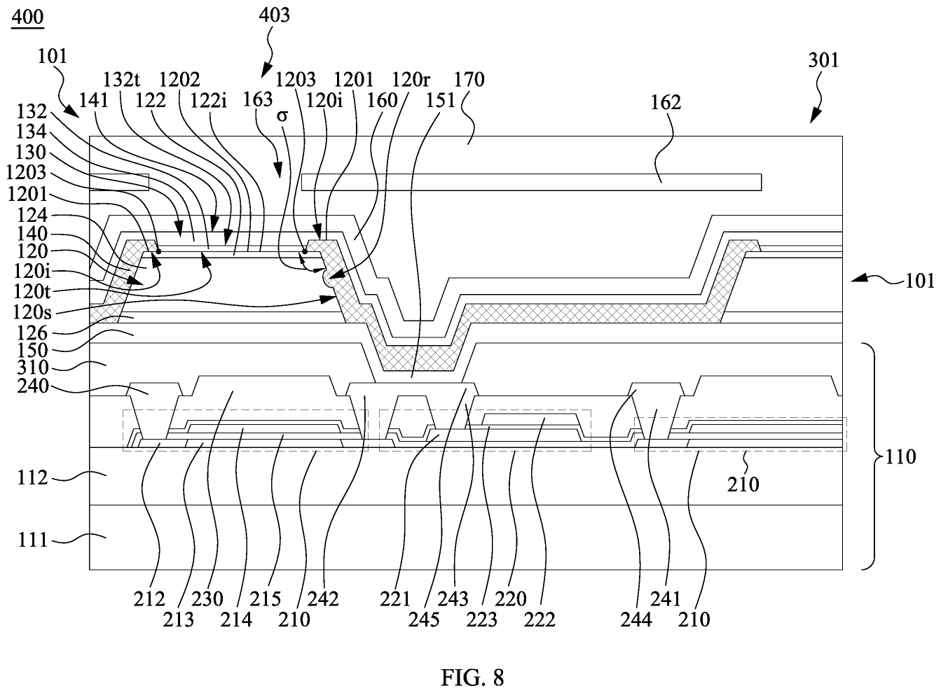

FIG. 8 shows a section diagram of a display device 400 according to some embodiments of the present disclosure. In some embodiments, as shown in FIG. 8, the display device 400 includes a regular pixel 301 and a dark pixel 403, wherein light cannot enter the dark pixel 403. In some embodiments, the quantum efficiencies of the regular pixel 301 and the dark pixel 403 are compared so as to learn the background noise of the display device 400. In some embodiments, the display device 400 includes a regular pixel 301, a dark pixel 402 and a dark pixel 403.

In some embodiments, the dark pixel 403 includes the second shielding metal layer 162, which is located on the sensing unit 101 and the first shielding metal layer 160 and is disposed in a flat layer 170. The second shielding metal layer 162 has an opening 163 and the first shielding metal layer 160 does not have any openings, such that light cannot enter the sensing unit 101. In some embodiments, the opening 163 of the second shielding metal layer 162 partially overlaps with the opening 141 of the dielectric layer 140. The width of the opening 163 of the second shielding metal layer 162 and the width of the opening 141 of the dielectric layer 140 may be equal or different.

In some embodiments, neither the first shielding metal layer 160 of the dark pixel 403 nor the second shielding metal layer 162 has any opening.

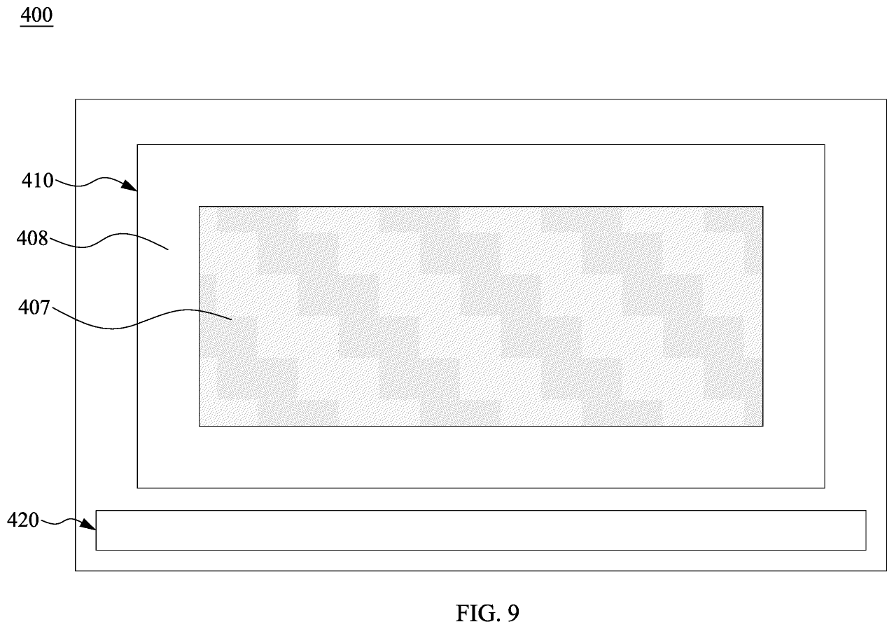

FIG. 9 to FIG. 11 are top views of a display device 400 according to some embodiments of the present disclosure. For example, the display device 400 includes an active area 410, and one or more inactive areas 420 disposed around the active area 410. The active area 410 includes an array 407 of regular pixels 301, and an array 408 of dark pixels 402 or an array 409 of dark pixels 403, or includes the array 407, the array 408 and the array 409. The inactive area 420 may be adjacent to one or more sides of the active area 410. In some embodiments, as shown in FIG. 9 to FIG. 11, the inactive area 420 and the active area 410 are individually rectangular in shape. However, it should be understood that, the arrangement and shapes of the inactive area 420 and the active area 410 are not specifically limited, and any shapes suitable for electronic apparatus adopting display devices may be used. The active area of the display device may be rectangular, pentagonal, hexagonal, circular or ellipsoidal in shape. In some embodiments, the inactive area 420 includes, for example but not limited to, a printed circuit board, a chip, a display panel driving integrated circuit (DDIC) and a touch and display driving integration (TDDI).

In some embodiments, as shown in FIG. 9, the array 408 of the dark pixels 402 encircles the array 407 of the regular pixels 301. In some embodiments, the array 409 of the dark pixels 403 encircles the array 407.

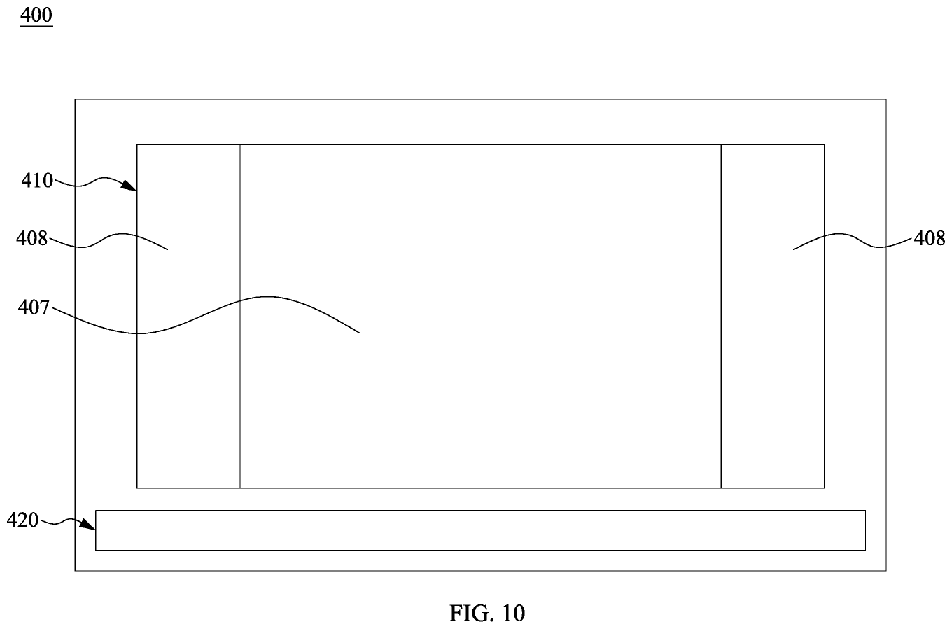

In some embodiments, as shown in FIG. 10, in the active area 410, the array 408 of the dark pixels 402 is disposed on two sides of the array 407 of the regular pixels 401. In some embodiments, the array 409 of the dark pixels 403 is disposed on two sides of the array 407.

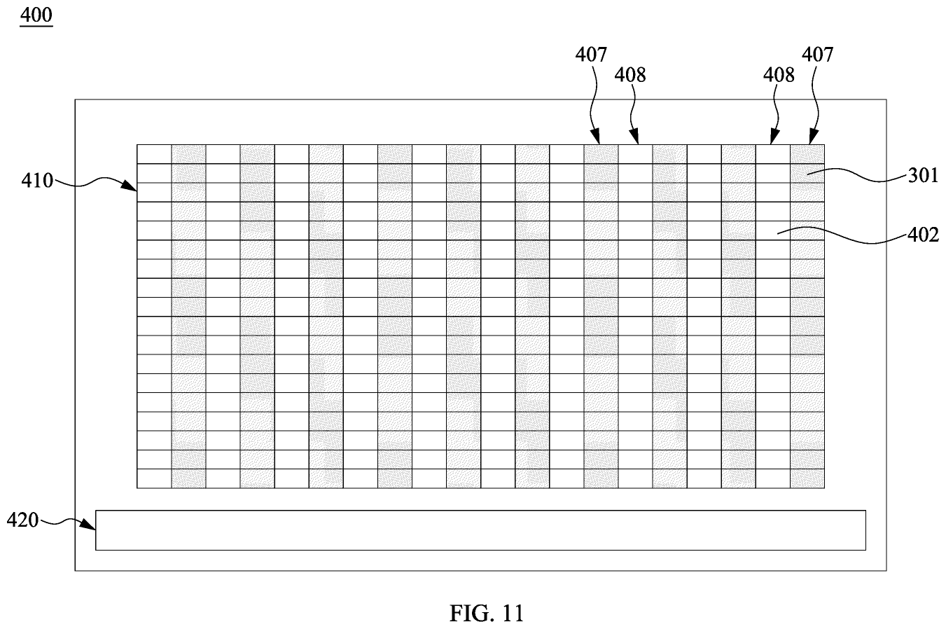

In some embodiments, as shown in FIG. 11, in the active area 410, the array 408 of the dark pixels 402 and the array 407 of the regular pixels 401 are arranged in an alternating manner. In some embodiments, the array 409 of the dark pixels 403 and the array 407 are arranged in an alternating manner.

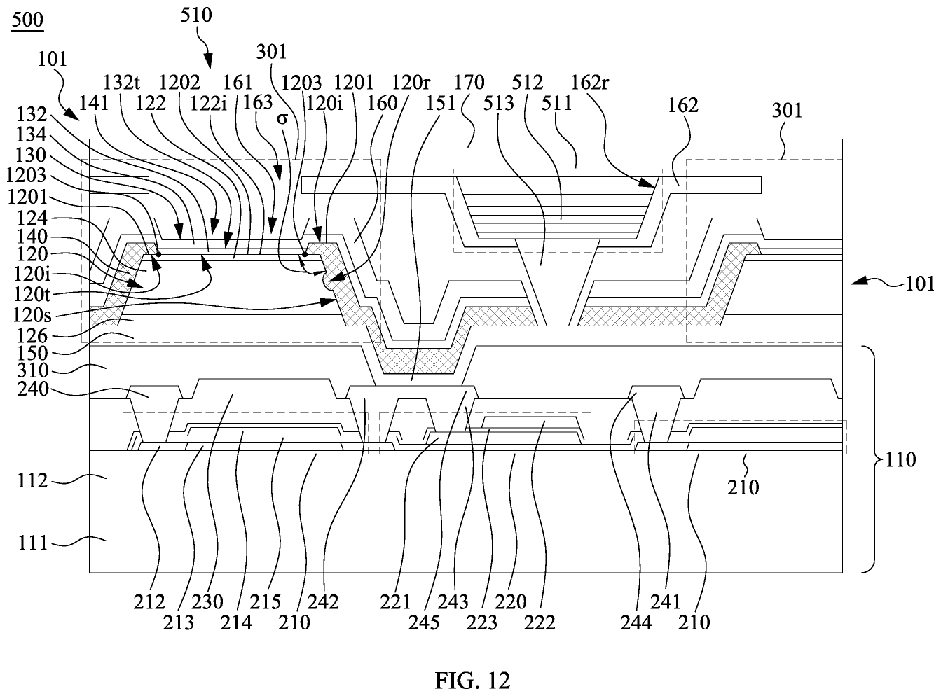

FIG. 12 shows a section diagram of a display device 500 according to some embodiments of the present disclosure. In some embodiments, as shown in FIG. 12, the display device 500 includes a display element 510, which includes a light-emitting unit 511 and a sensing unit 101. In some embodiments, the display element 510 includes a light-emitting unit 511 and at least one regular pixel 301.

In some embodiments, the light-emitting unit 511 is an OLED light-emitting unit. In some embodiments, the light-emitting unit 511 includes a light-emitting layer 512. The light-emitting layer 512 includes a light-emitting material, for example but not limited to, an organic light-emitting material. In some embodiments, the light-emitting unit 511 is disposed on the second shielding metal layer 162. In some embodiments, a distance from the light-emitting unit 511 to the substrate 110 is greater than a distance from the regular pixel 301 to the substrate 110. In some embodiments, the second shielding metal layer 162 includes a recessed portion 162r, and the light-emitting unit 511 is disposed in the recessed portion 162r. In some embodiments, from a section view, the recessed portion 162r of the second shielding metal layer 162 is encircled by the flat layer 170, and the light-emitting unit 511 is encircled by the recessed portion 162r of the second shielding metal layer 162.

In some embodiments, the light-emitting unit 511 is electrically connected to the first electrode 150 through a connecting structure 513. In some embodiments, the connecting structure 513 is encircled by the flat layer 170. In some embodiments, the connecting structure 513 passes through the first shielding metal layer 160, is disposed on the second electrode 130 and the dielectric layer 140, and electrically connects the light-emitting unit 511 to the first electrode 150.

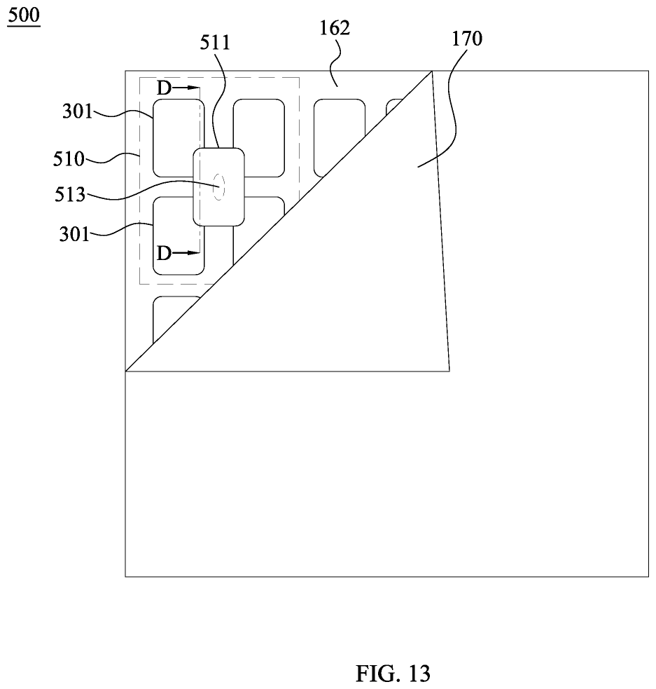

FIG. 13 shows a top view of the display device 500 in FIG. 12 (the section in FIG. 12 is obtained along the section line D-D in FIG. 13). In some embodiments, as shown in FIG. 13, in the display element 510, each of a plurality of regular pixels 301 partially overlaps with the light-emitting unit 511, for example but not limited to, each of four regular pixels 301 partially overlaps with the light-emitting unit 511. The light-emitting unit 511 does not completely cover the regular pixels 301, allowing light to enter the regular pixels 301. In some embodiments, the light-emitting unit 511 is encircled by a plurality of regular pixels 301. In some embodiments, the connecting structure 513 is encircled by a plurality of regular pixels 301. Shapes, numbers and configurations of the light-emitting units 510 and the regular pixel 301 may be adopted differently according to user preferences, and are not specifically limited. In some embodiments, the display element 510 includes the light-emitting element 511, and the regular pixels 301 located on two sides of the light-emitting unit 511.

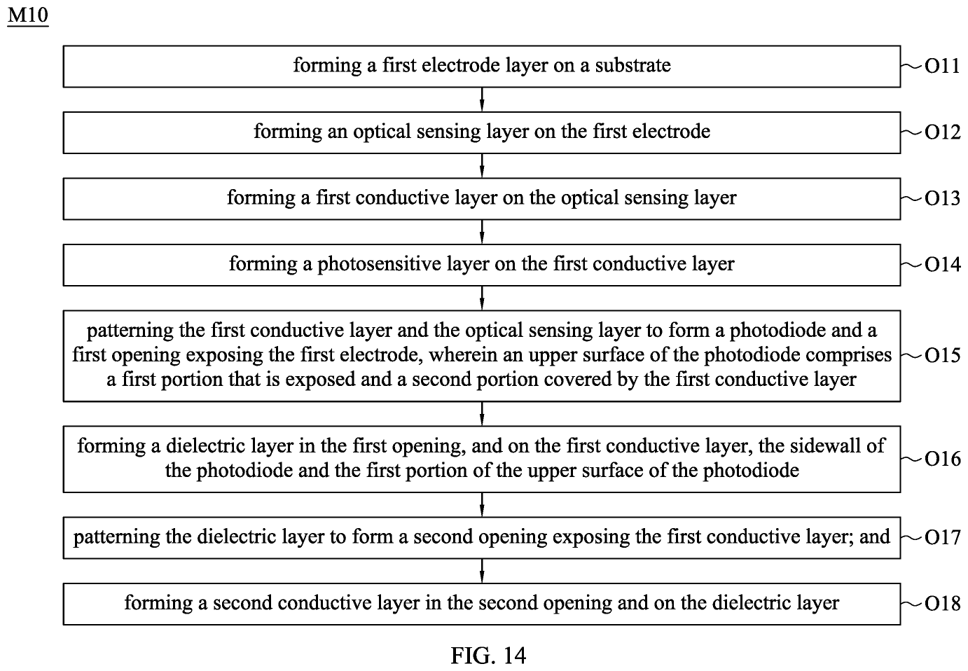

To further describe the present disclosure, FIG. 14 shows a flowchart of a method M10 for manufacturing a display device according to some embodiments. The method M10 for manufacturing the display device 100, 200, 300 or 400 includes the following steps: O11 of forming a first electrode layer on a substrate; O12 of forming an optical sensing layer on the first electrode; O13 of forming a first conductive layer on the optical sensing layer; O14 of forming a photosensitive layer on the first conductive layer; O15 of patterning the first conductive layer and the optical sensing layer to form a photodiode and a first opening exposing the first electrode, wherein an upper surface of the photodiode includes a first portion that is exposed and a second portion covered by the first conductive layer; O16 of forming a dielectric layer in the first opening, and on the first conductive layer, the sidewall of the photodiode, the first portion of the upper surface of the photodiode; O17 of patterning the dielectric layer to form a second opening exposing the first conductive layer; and O18 of forming a second conductive layer in the second opening and on the dielectric layer. It should be noted that, the flowchart in FIG. 12 is for illustration purposes only, and is not to be construed as limiting the steps to a specific order. Steps O11 to O18 may be in different orders according to different implementations.

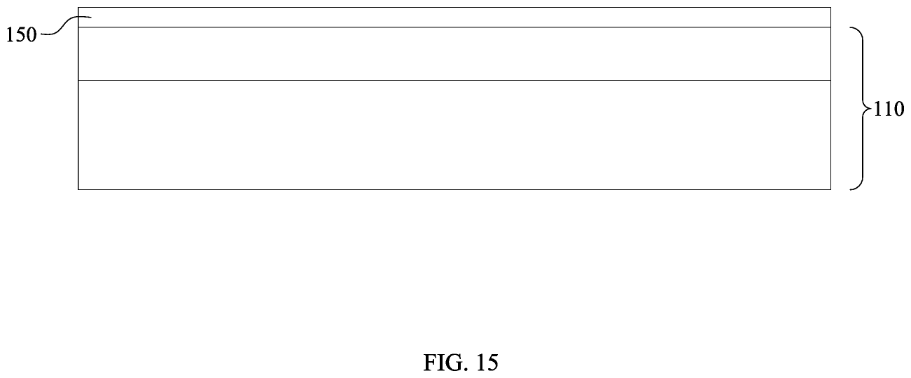

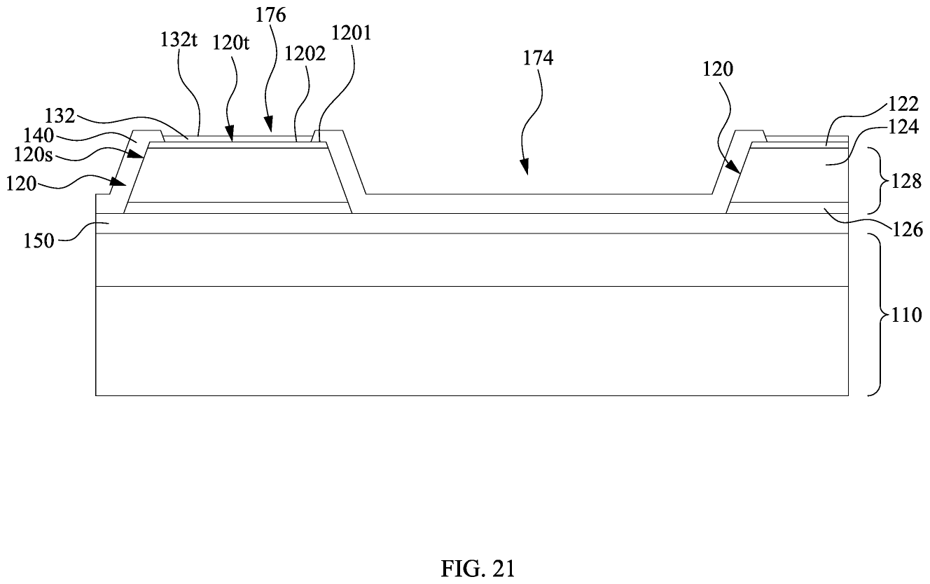

Referring to FIG. 15 to FIG. 23, FIG. 15 to FIG. 23 depict a method for manufacturing a display device according to some embodiments of the present disclosure. FIG. 15 to FIG. 23 are section diagrams along the line AA in FIG. 1.

As shown in FIG. 15, in step O11, a first electrode layer 150 is formed on a substrate 110. The substrate 110 may include a base material 111, a dielectric layer 112, a transistor 210, a capacitor 220, an interlayer dielectric structure 230, a connecting structure 240, a dielectric layer 310 and a planar layer 320. The foregoing components are similar to those of the display device 100 above, and repeated description is omitted herein. The first electrode layer 150 is formed on the substrate 110. In some embodiments, the first electrode layer 150 is formed on the top surface of the substrate 110 by a deposition technique, for example but not limited to, deposition techniques such as atom layer deposition (ALD), chemical vapor deposition (CVD), physical vapor deposition (PVD), sputtering, electroplating, laser induced thermal imaging (LITI), jet-ink printing, shadow masking or wet coating.

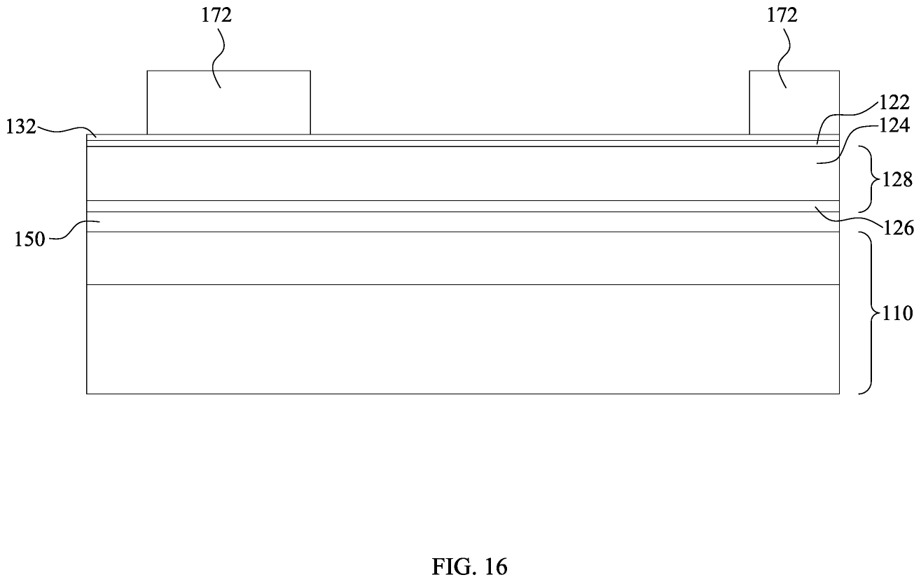

As shown in FIG. 16, in step O12, an optical sensing layer 128 is formed on the first electrode 150. In some embodiments, the optical sensing layer 128 is formed on the top surface of the first electrode layer 150 by a deposition technique. In some embodiments, forming the optical sensing layer 128 includes sequentially stacking an N-type doped layer 126, an intrinsic layer 124 and a P-type doped layer 122 on the first electrode 150.

Again referring to FIG. 16, in step O13, a first conductive layer 132 is formed on the optical sensing layer 128. In some embodiments, conformal deposition is performed to form the first conductive layer 132 on the top surface of the optical sensing layer 128. In some embodiments, the first conductive layer 132 is formed on the top surface of the P-type doped layer 122.

Again referring to FIG. 16, in step O14, a photosensitive layer 172 is formed on the first conductive layer 132. In some embodiments, as shown in FIG. 14, the photosensitive layer 172 is applied on the top surface of the first conductive layer 132. In some embodiments, the photosensitive layer 172 is disposed by means of spin coating or spraying coating. In some embodiments, the photosensitive layer 172 is further patterned by a lithography process to remove a portion of the photosensitive layer 172, the remaining portion of the photosensitive layer 172 is used for positioning an optical sensing unit 101, and a portion of the first conductive layer 132 is exposed through the photosensitive layer 172. In some embodiments, the pattern of the photosensitive layer 172 is designed for forming the sensing units 101 arranged in an array.

In some embodiments, the photosensitive layer 172 may include a positive photoresist or a negative photoresist. In some embodiments, the photosensitive layer 172 may include an organic material or an inorganic material. In some embodiments, the organic material may include, for example, phenolic formaldehyde resin, epoxy resin, ether, amine, rubber, acrylic, acrylic resin, acrylic epoxy, and acrylic melamine. In some embodiments, the inorganic material may include, for example, metal oxide and silicide. In some embodiments, the photosensitive layer 172 may include a layer consisting of one material. In some embodiments, the photosensitive layer 172 may include a plurality of layers consisting of a plurality of different materials, for example, an organic material layer stacked on an inorganic material layer.

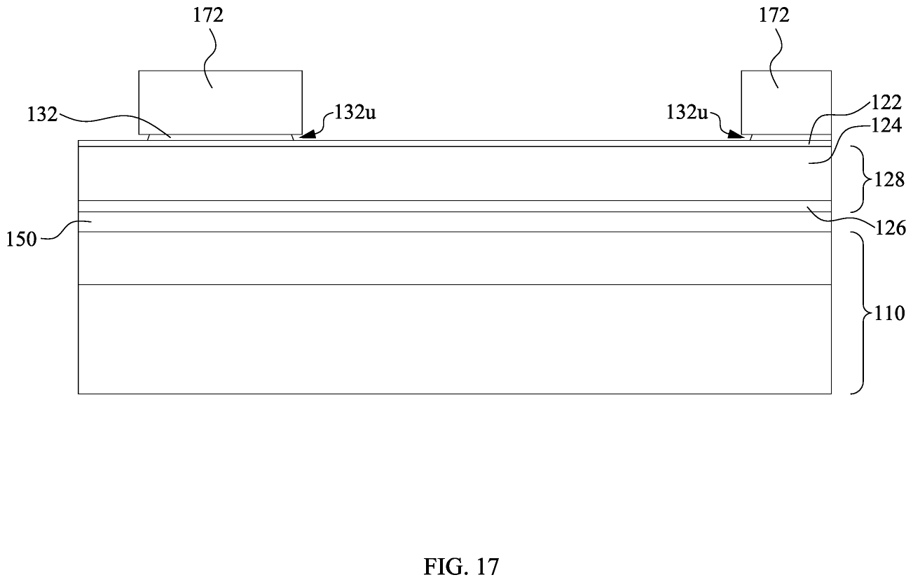

Referring to FIGS. 17, 18 and 19, in step O15, the first conductive layer 132 and the optical sensing layer 128 are patterned to form a photodiode 120 and a first opening 174 exposing the first electrode 150. In some embodiments, the first conductive layer 132 is patterned by dry etching. In some embodiments, as shown in FIG. 17, the patterned first conductive layer 132 has an undercut 132u. In some embodiments, due to the presence of the undercut, the width of the patterned first conducive layer 132 is smaller than the width of the photosensitive layer 172.

In some embodiments, the photosensitive layer 128 is patterned by means of wet etching to form a photodiode 120 located between the substrate 110 and the first conductive layer 132, and to form an opening 174 located on the photodiode 120. An upper surface 120t of the photodiode 120 includes a first portion 1201 that is exposed and a second portion 1202 covered by the first conductive layer 132. In some embodiments, a sidewall 120s of the photodiode 120 has a rough surface. In some embodiments, the depth d of the first opening 174 is 100 to 800 nm. In some embodiments, the upper surface of the first electrode 150 is partially exposed through the photodiode 120.

In some embodiments, the optical sensing layer 128 is patterned, such that the sidewall 120s and the upper surface 120t of the formed photodiode 120 have a radius angle σ in between. The range of the radius angle σ is within a range of 75 degrees to 160 degrees.

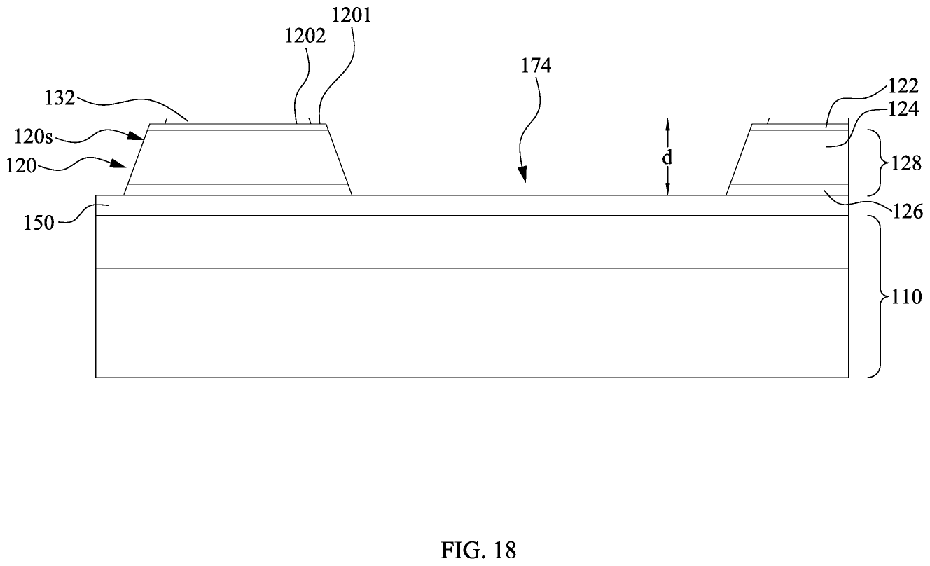

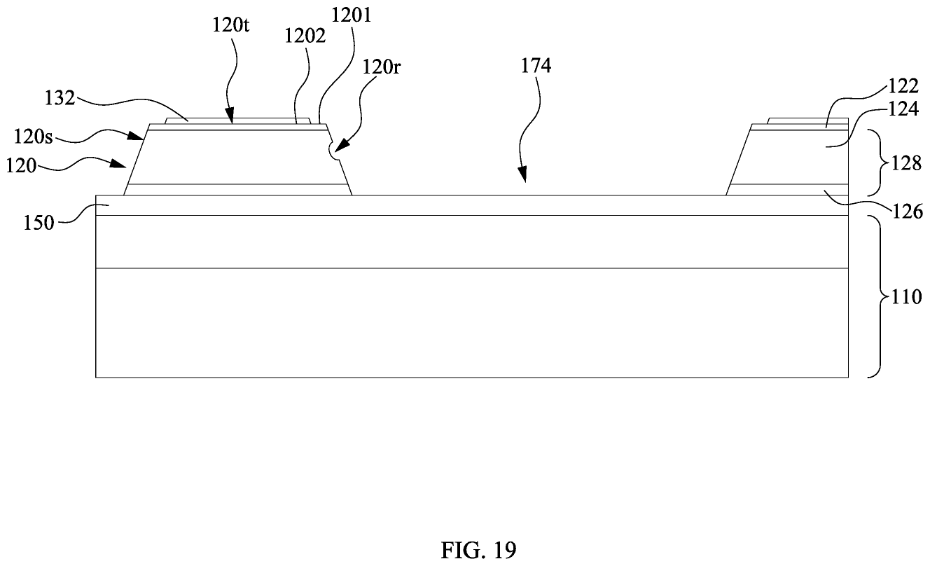

In some embodiments, patterning the optical sensing layer 128 includes at least two steps. The first step is substantial removal, and forms the photodiode 120 shown in FIG. 18. In some embodiments, as shown in FIG. 19, patterning the optical sensing layer 128 causes an undercut, such that a recess 120r is formed on a sidewall 120s of the photodiode 120. In some embodiments, the recess 120r is near the upper surface 120t of the photodiode 120. In some embodiments, patterning the optical sensing layer 128 includes only substantial removal.

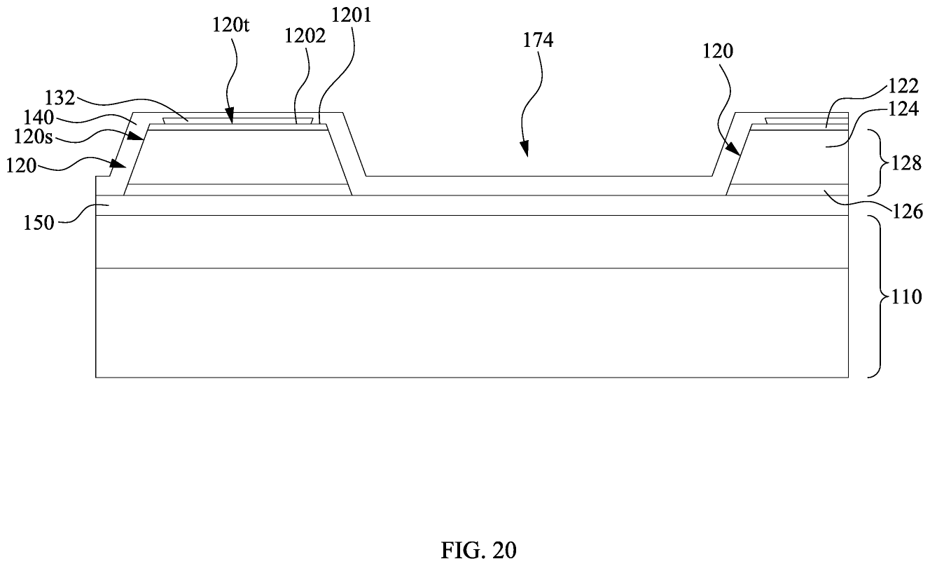

Referring to FIG. 20, in step O16, a dielectric layer 140 is formed in the first opening 174, and on the first conductive layer 132, the sidewall 120s of the photodiode 120, and the first portion 1201 of the upper surface 120t of the photodiode 120. The dielectric layer 140 is disposed according to the surface shapes of the first conductive layer 132 and the photodiode 120, and covers the exposed portion of the first electrode 150. In some embodiments, the dielectric layer 140 is further formed in the recess 120r. In some embodiments, the dielectric layer 140 is formed by a deposition technique.

Referring to FIG. 2, in step O17, the dielectric layer 140 is patterned to form a second opening 176 exposing the first conductive layer 132. In some embodiments, the dielectric layer 140 is patterned by disposing a photosensitive layer (not shown) on the dielectric layer 140. In some embodiments, the dielectric layer 140 is patterned to completely expose the upper surface 132t of the first conductive layer 132 through the second opening 176. In some embodiments, the dielectric layer 140 is patterned to partially expose the upper surface 132t of the first conductive layer 132 through the second opening 176. In some embodiments, step O17 causes the thickness uniformity of the first conductive layer 132 to be greater than the thickness uniformity of the second portion 1202 of the upper surface 120t of the photodiode 120.

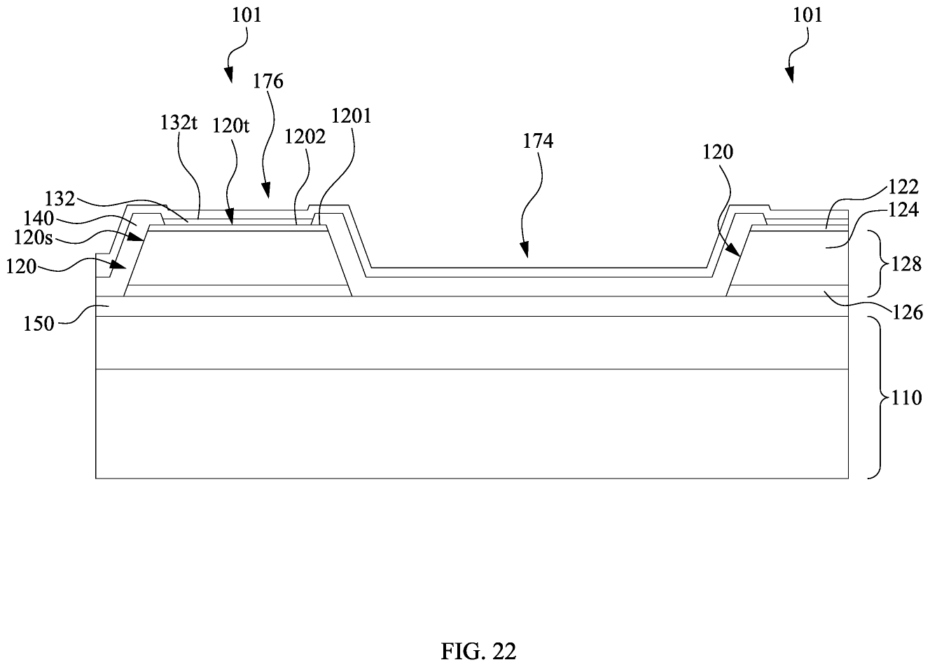

Referring to FIG. 22, in step O18, a second conductive layer 134 is formed in the second opening 176 and on the dielectric layer 140. The first conductive layer 132 and the second conductive layer 134 form the second electrode 130. In some embodiments, the second conductive layer 134 is formed by a deposition technique. In some embodiments, the second conductive layer 134 is continuously arranged according to the surface shapes of the first conductive layer 132 and the dielectric layer 140. In some embodiments, a plurality of sensing units 101 share the second conductive layer 134. In some embodiments, surface treatment is performed on the second conductive layer 134 by plasma, such that the thickness uniformity of the second conductive layer 134 is greater than the thickness uniformity of the upper surface 120t of the photodiode 120.

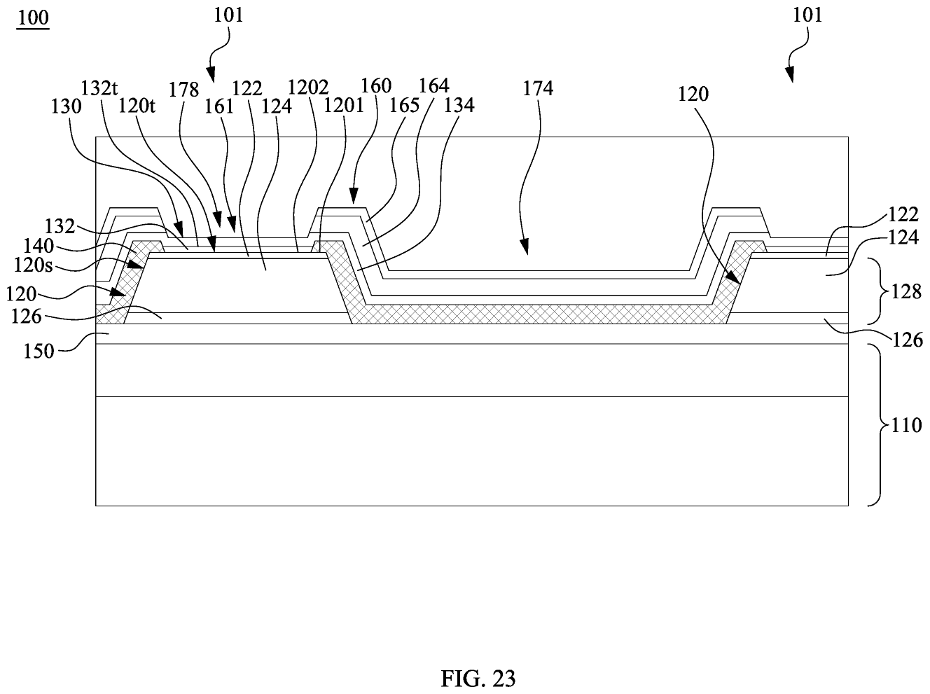

Referring to FIG. 23, in some embodiments, the method M10 further includes forming a first shielding metal layer 160 on the second conductive layer 134, and patterning the first shielding metal layer 160 to form a third opening 178 exposing the second conductive layer 134. In some embodiments, the first shielding metal layer 160 is disposed by a deposition technique. In some embodiments, the first shielding metal layer 160 is patterned by disposing a photosensitive layer (not shown) on the first shielding metal layer 160.

In some embodiments, forming the first shielding metal layer 160 further includes forming an aluminum layer 164 on the second electrode 130, and forming an ITO layer 165 on the aluminum layer 164.

In some embodiments, the method M10 further includes forming a first opening 161 on the first shielding metal layer 160. In some embodiments, the first opening 161 is formed by means of dry etching the ITO layer 165 and wet etching the aluminum layer 164.

In some embodiments, the method M10 further includes forming a flat layer 170 on the first shielding metal layer 160. In some embodiments, the flat layer 170 is disposed by means of spin coating or spraying coating. In some embodiments, the flat layer 170 is further heated.

In accordance with some embodiments of the disclosure, a display device includes a substrate, and a sensing unit disposed on the substrate. The sensing unit includes a photodiode, a dielectric layer and a second electrode. The photodiode is disposed on the substrate, and includes a sidewall and an upper surface. The dielectric layer is disposed on the substrate and on the sidewall of the photodiode, and is in contact with a first portion of the upper surface of the photodiode. The second electrode includes a first conductive layer and a second conductive layer. The first conductive layer is disposed on a second portion of the upper surface of the photodiode, and the second conductive layer is disposed on the dielectric layer and on the first conductive layer. The first portion of the upper surface of the photodiode encircles the second portion.

In accordance with some embodiments of the disclosure, a display device includes a substrate, a photodiode, a first conductive layer, a second conductive layer, and a dielectric layer. The photodiode is disposed on the substrate and included an upper surface. The first conductive layer is disposed on the photodiode. The second conductive layer is disposed between the photodiode and the first conductive layer, and electrically connected to the photodiode and the first conductive layer. The dielectric layer is disposed between the photodiode and the first conductive layer, and adjacent to the second conductive layer. The upper surface of the photodiode has a first joint joined with the second conductive layer and the dielectric layer.

In accordance with some embodiments of the disclosure, a method for manufacturing a display device includes forming a first electrode layer on a substrate; forming an optical sensing layer on the first electrode; forming a first conductive layer on the optical sensing layer; and forming a photosensitive layer on the first conductive layer. The method further includes patterning the first conductive layer and the optical sensing layer to form a photodiode and a first opening exposing the first electrode, wherein an upper surface of the photodiode comprises a first portion that is exposed and a second portion covered by the first conductive layer; forming a dielectric layer in the first opening, and on the first conductive layer, the sidewall of the photodiode and the first portion of the upper surface of the photodiode; patterning the dielectric layer to form a second opening exposing the first conductive layer; and forming a second conductive layer in the second opening and on the dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein, may be utilized according to the present invention. Accordingly, the appended claims are intended to include within their scope such processes, machines, manufacture, compositions of matter, means, methods and steps.

What is claimed is:

1. A display device, comprising:
a substrate; and
an optical sensing unit, disposed on the substrate, the sensing unit comprising:
a photodiode, disposed on the substrate, the photodiode comprising a sidewall and an upper surface;
a dielectric layer, disposed on the substrate and on the sidewall of the photodiode, being in contact with a first portion of the upper surface of the photodiode; and
a second electrode, comprising a first conductive layer and a second conductive layer, the first conductive layer being disposed on a second portion of the upper surface of the photodiode, the second conductive layer being disposed on the dielectric layer and on the first conductive layer;
wherein, the first portion of the upper surface of the photodiode encircles the second portion.

2. The display device according to claim 1, wherein the dielectric layer encircles the first conductive layer.

3. The display device according to claim 1, wherein an upper surface of the first conductive layer has a first portion in contact with the dielectric layer and a second portion in contact with the second conductive layer, and the first portion of the upper surface of the first conductive layer encircles the second portion.

4. The display device according to claim 1, wherein a thickness of the second electrode is greater than a thickness of the dielectric layer.

5. The display device according to claim 1, wherein thickness uniformity of the first conductive layer is greater than thickness uniformity of the second portion of the upper surface of the photodiode.

6. The display device according to claim 1, wherein thickness uniformity of the second conductive layer is greater than thickness uniformity of the upper surface of the photodiode.

7. The display device according to claim 1, wherein the sidewall and the upper surface of the photodiode have a radius angle therebetween, and the radius angle is within a range of 75 degrees to 160 degrees.

8. The display device according to claim 1, wherein the optical sensing unit further comprises a first electrode disposed between the substrate and the photodiode.

9. The display device according to claim 1, wherein the upper surface of the photodiode comprises a P-type doped layer.

10. The display device according to claim 1, wherein the second conductive layer and the dielectric layer are conformal with the first conductive layer.

11. The display device according to claim 1, further comprising a shielding metal layer disposed on the second electrode.

12. A display device, comprising:
a substrate;
a photodiode, disposed on the substrate, comprising an upper surface;
a first conductive layer, disposed on the photodiode;
a second conductive layer, disposed between the photodiode and the first conductive layer, and electrically connected to the photodiode and the first conductive layer; and
a dielectric layer, disposed between the photodiode and the first conductive layer, and being adjacent to the second conductive layer;
wherein, the upper surface of the photodiode has a first joint joined with the second conductive layer and the dielectric layer.

13. The display device according to claim 12, wherein the photodiode further comprises a sidewall, and the dielectric layer is disposed on the sidewall of the photodiode and on the substrate.

14. The display device according to claim 12, wherein one end of the second conductive layer and one end of the upper surface of the photodiode further comprise a first interface therebetween, the first interface is between the dielectric layer and the photodiode, one end of the second conductive layer and the other end of the second conductive layer comprise a second interface therebetween, and the second interface is between the second conductive layer and the photodiode.

15. A method for manufacturing a display device, comprising:
forming a first electrode layer on a substrate;
forming an optical sensing layer on the first electrode;
forming a first conductive layer on the optical sensing layer;
forming a photosensitive layer on the first conductive layer;
patterning the first conductive layer and the optical sensing layer to form a photodiode and a first opening exposing the first electrode, wherein an upper surface of the photodiode comprises a first portion that is exposed and a second portion covered by the first conductive layer;
forming a dielectric layer in the first opening, and on the first conductive layer, the sidewall of the photodiode and the first portion of the upper surface of the photodiode;
patterning the dielectric layer to form a second opening exposing the first conductive layer; and
forming a second conductive layer in the second opening and on the dielectric layer.

16. The method according to claim 13, wherein the first conductive layer is patterned by means of dry etching and the optical sensing layer is patterned by means of wet etching.

17. The method according to claim 13, further comprising:
performing surface treatment on the second conductive layer by plasma.

18. The method according to claim 13, further comprising:
forming a recess on a sidewall of the photodiode; and
forming the dielectric layer in the first opening and the recess, and on the first conductive layer, the sidewall and the first portion of the upper surface of the photodiode.

19. The method according to claim 13, wherein a depth of the first opening is within a range of 100 nm to 800 nm.

20. The method according to claim 13, further comprising:
forming a shielding metal layer on the second conductive layer; and
patterning the shielding metal layer to form a third opening exposing the second conductive layer.
